(19) United States
(12) Patent Application Publication
(10) Pub. No.: US 2008/0160695 A1
(43) Pub. Date: Jul. 3, 2008

(54) METHOD OF FABRICATING SEMICONDUCTOR DEVICE

(76) Inventor: Yong-Wook Shin, Seoul (KR)

Correspondence Address: SHERR & NOURSE, PLLC, 620 HERNDON PARKWAY, SUITE 200, HERNDON, VA, 20170, US

(21) Appl. No.: 11/959,246

(22) Filed: Dec. 18, 2007

(30) Foreign Application Priority Data
Dec. 28, 2006 (KR) 10-2006-0135923

(51) Int. Cl. H01L 21/336

(52) U.S. Cl. 438/264; 257/E21.422

(57) ABSTRACT

A method of forming a floating gate of a flash memory device that can include steps of forming isolation layers in a semiconductor substrate to define active regions, forming a tunnel oxide layer over the active regions of the semiconductor substrate and forming a gate layer by depositing doped polysilicon over the isolation layers and the tunnel oxide layer, forming photoresist patterns having apertures through which portions of the gate layer spatially corresponding to the isolation layers are exposed, forming ion implantation regions by implanting impurity ions into the exposed portions of the gate layer using the photoresist patterns as masks, forming floating gates by etching the ion implantation regions using the photoresist patterns as masks, and then removing the photoresist patterns.

The present application claims priority under 35 U.S.C. 119 to Korean Patent Application No. 10-2006-0135923 (filed on Dec. 28, 2006), which is hereby incorporated by reference in its entirety.

### BACKGROUND

Flash memory is a semiconductor device that can include non-volatile memory devices. Non-volatile memory devices using polysilicon as a single layer have been used, and may have a dual layer structure that may include a floating gate and a control gate made of polysilicon. In order to improve the degree of integration of flash memory devices, it may become necessary to narrow the distance between floating gates.

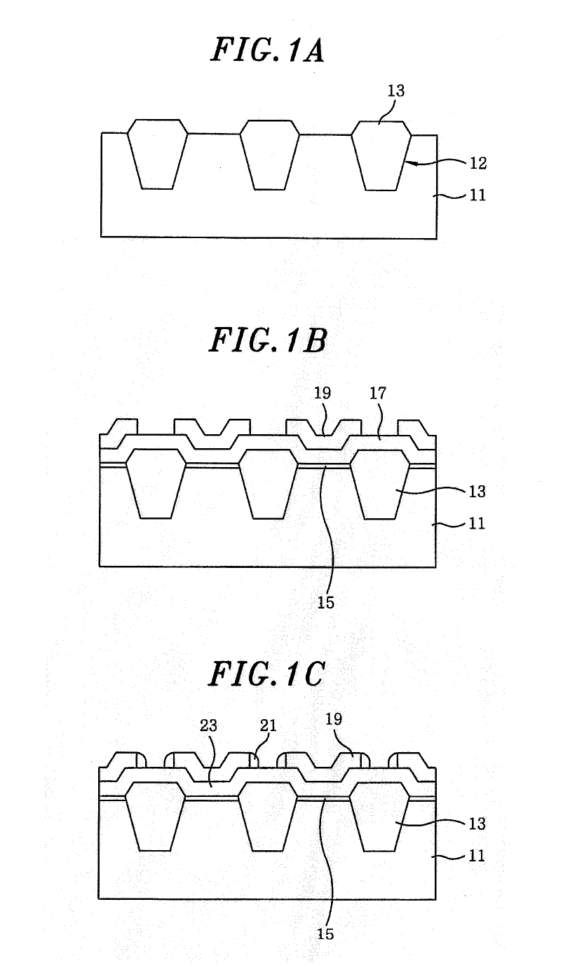

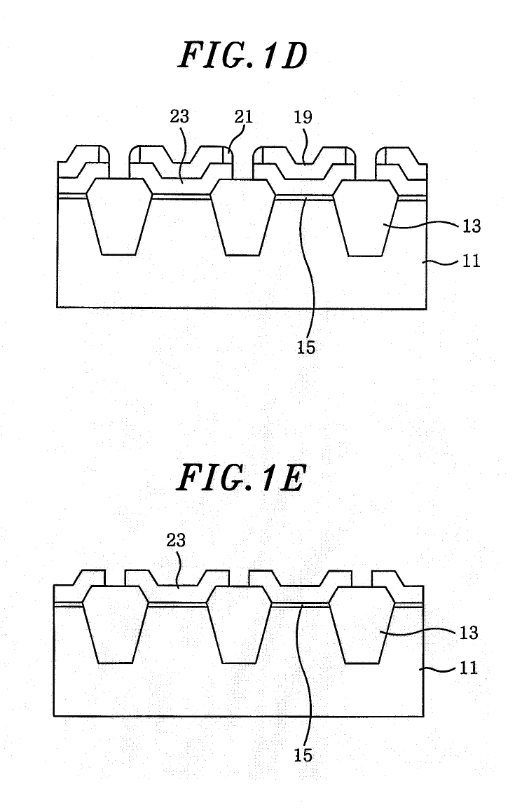

As illustrated in example FIG. 1A, a plurality of trenches 12 may be formed in semiconductor substrate 11. Trenches 12 may be gap-filled with an insulating material such as silicon oxide. The gap-filled trenches 12 may then be polished by a shallow trench isolation (STI) method such as chemical mechanical polishing (CMP) to form isolation layers 13 defining active regions.

As illustrated in example FIG. 1B, tunnel oxide layer 15 may then be formed to a thickness of about 100 Å on and/or over the active regions of semiconductor substrate 11. Polysilicon may then be deposited to a thickness of about 1000 Å on and/or over isolation layers 13 and tunnel oxide layer 15 to form gate layer 17. Gate layer 17 may be composed of doped polysilicon.

A layer composed of tetraethyl orthosilicate (TEOS) may then be then deposited by a low-pressure CVD (LPCVD) method to a thickness of 2300 Å on and/or over gate layer 17 to form hard mask layer 19.

Portions of hard mask layer 19 corresponding to isolation layers 13 may then be patterned by a photolithographic method so that they are exposed. The photolithographic method may be performed using deep ultraviolet (DUV) equipment so that the distance between hard mask layers 19 becomes about 0.2 um.

As illustrated in example FIG. 1C, after patterning hard mask layer 19, TEOS may then be deposited by a LPCVD method to a thickness of about 750 Å. The deposited TEOS may then be etched back by a reactive ion etch (RIE) method without a photomask to a thickness greater than the deposition thickness to expose gate layers 17 between hard mask layers 19. Thus, spacers 21 having a thickness of about 50 to 60 nm may be formed on and/or over the sidewalls of hard mask layers 19.

As illustrated in example FIG. 1D, the exposed portions of gate layers 17 may then be removed by a dry etch method such as RIE, by using hard mask layers 19 as a mask to form floating gates 23. Because of spacers 21, the distance between resulting floating gates 23 may be about 90 nm. Hard mask layers 19 used as the mask may then be etched under the influence of the etch process, but finally remain on and/or over gate layers 17 to a thickness of about 10 Å.

As illustrated in example FIG. 1E, hard mask layers 19 and spacers 21 may then be selectively etched by fluoric acid (HF) to form gate structures.

As described above, spacers may be formed on and/or over the sidewalls of a hard mask layer formed on and/or over a gate layer and the gate layer etched using the hard mask layer and the spacers as a mask to form a floating gate of a flash memory device having a narrow gap. However, this process may be complicated.

### SUMMARY

Embodiments relate to a method of fabricating semiconductor device in which a floating gate can be formed by a simple process employing a single photolithographic process.

Embodiments relate to a method of fabricating a flash memory device that can include at least one of the following steps: forming a plurality of isolation layers in a semiconductor substrate; forming a tunnel oxide layer directly over the semiconductor substrate; forming a gate layer composed of doped polysilicon over the isolation layers and the tunnel oxide layer; exposing the gate layer at a region which spatially corresponds to a respective one of the isolation layers; forming an ion implantation region in the exposed regions of the gate layer; and then forming floating gates by etching the ion implantation regions.

Embodiments relate to a method of fabricating a flash memory device that can include at least one of the following steps: forming a plurality of shallow trench isolation layers in a semiconductor substrate having active regions; forming a tunnel oxide layer over the active regions of the semiconductor substrate; forming a gate layer over the semiconductor substrate including the shallow trench isolation layers and the tunnel oxide layer; forming ion implantation regions in portions of the gate layer corresponding spatially to a respective one of the shallow trench isolation layers; and then forming floating gates over the semiconductor substrate including the shallow trench isolation layers and the tunnel oxide layer.

Embodiments relate to a method of fabricating a flash memory device that can include at least one of the following steps: forming a plurality of shallow trench isolation layers in a semiconductor substrate having active regions; forming a tunnel oxide layer over the active regions of the semiconductor substrate; forming a gate layer over the semiconductor substrate including the shallow trench isolation layers and the tunnel oxide layer; forming photoresist patterns having apertures through which portions of the gate layer spatially corresponding to the isolation layers are exposed; forming ion implantation regions by implanting impurity ions into the exposed portions of the gate layer using the photoresist patterns as masks; forming floating gates by etching the ion implantation regions using the photoresist patterns as masks, and then removing the photoresist patterns.

### DRAWINGS

Example FIGS. 1A to 1E illustrate a process of fabricating a semiconductor device.

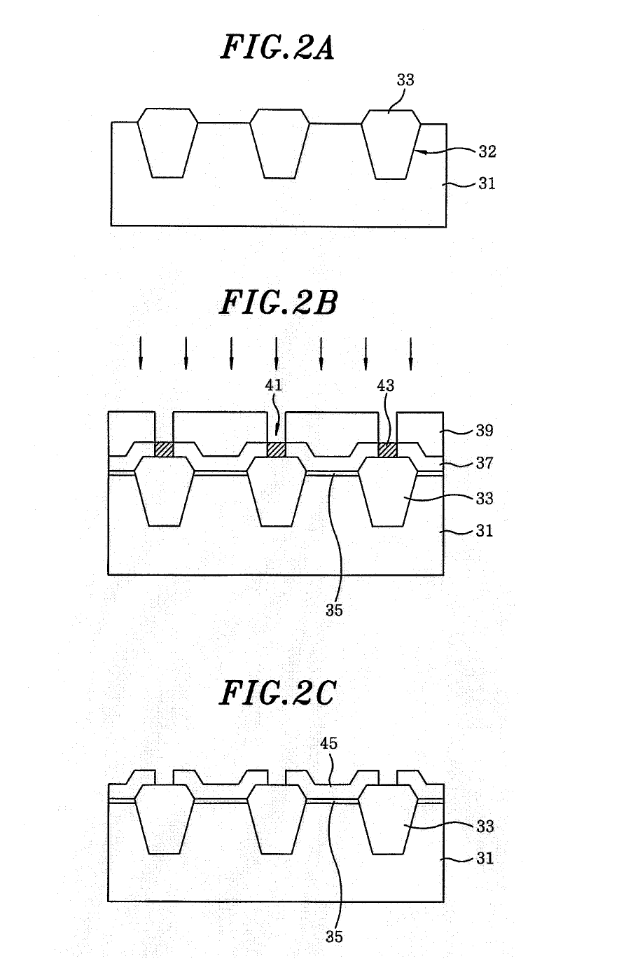

Example FIGS. 2A to 2C illustrate a process of fabricating a semiconductor device, in accordance with embodiments.

### DESCRIPTION

As illustrated in example FIG. 2A, a flash memory device provided in accordance with embodiments can include a plurality of trenches 32 formed in semiconductor substrate 31. Trenches 32 can then be gap-filled with an insulating material such as silicon oxide. The insulating material can then be polished by an STI method such as CMP to form a plurality of isolation layers 33 defining active regions in semiconductor substrate 31.

As illustrated in example FIG. 2B, tunnel oxide layer 35 can then be deposited by a thermal oxidization method on and/or over active regions of semiconductor substrate 31 to a thickness of about 50 to 150 Å. Gate layer 37 can then be formed on and/or over semiconductor substrate 31 including isolation layers 33 and tunnel oxide layer 35. Gate layer 35 can be formed by depositing doped polysilicon to a thickness of about 500 to 1500 Å on and/or over isolation layers 33 and tunnel oxide layer 35.

A photoresist can then be coated on and/or over gate layer 37 by a spin coating method. Portions of the photoresist corresponding to isolation layers 33 can be exposed and developed to form photoresist patterns 39 having apertures 41 through which the uppermost surface of gate layer 37 can be exposed. An impurity ion such as B, P or As can then be implanted into the exposed portions through apertures 41 of gate layer 37 by using photoresist patterns 39 as a mask to form ion implantation regions 43. When the impurity ions are implanted, energy can then be controlled such that the arrival distance of the impurity ion is substantially identical to the total thickness of gate layer 37. Alternatively, an implantation angle of the impurity ions can be controlled in order to form an improved cell sidewall shape.

As illustrated in example FIG. 2C, ion implantation regions 43 exposed through apertures 41 can then be selectively etched by a dry etch method such as RIE, by using photoresist patterns 39 as a mask to form floating gates 45. When ion implantation regions 43 are formed, the implantation angle of the impurity ion can be controlled to enhance the sidewall profile of floating gates 45. Photoresist patterns 39 can then be removed.

In accordance with embodiments, if ion impurities of one of boron, phosphorus and arsenic are implanted into polysilicon, ion having strong energy can cause lattice distortion of the polysilicon. Accordingly, the etch rate can be increased since reaction of the ion and an etch gas can be activated at the time of etch. Accordingly, the ion-implanted portion can be etched more rapidly in a subsequent etch step.

Moreover, ion impurities can be implanted at a controlled implant angle. That is, by controlling the implanted angle, the ions can be implanted into a gate layer on which a photoresist has been coated near the aperture portion of a photoresist pattern. Thus, the sides of portions patterned when polysilicon is etched can have a substantially round configuration. Accordingly, an advantageous effect can be obtained in terms of retention or endurance used to evaluate reliability of flash cells.

Accordingly, the flash memory device provided in accordance with embodiments can also be advantageous in that a floating gate can be formed simply using a single photolithographic process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a plurality of isolation layers in a semiconductor substrate;
forming a tunnel oxide layer directly over the semiconductor substrate;
forming a gate layer composed of doped polysilicon over the isolation layers and the tunnel oxide layer;
exposing the gate layer at a region which spatially corresponds to a respective one of the isolation layers;
forming an ion implantation region in the exposed regions of the gate layer; and then
forming floating gates by etching the ion implantation regions.

2. The method of claim 1, wherein forming the ion implantation regions comprises controlling at least one of an implantation angle and the implantation energy.

3. The method of claim 1, further comprising, after forming the gate layer:
forming a photoresist over the gate layer; and then
forming a plurality of photoresist patterns and a plurality of apertures by performing a exposure and development process, wherein the plurality of apertures exposes the gate layer at a region which spatially corresponds to a respective one of the isolation layers.

4. The method of 3, further comprising, after forming the floating gates, removing the photoresist patterns.

5. The method of claim 3, wherein the photoresist is formed by a spin coating process.

6. The method of 1, wherein the impurity includes one of boron, phosphorus and arsenic.

7. The method of 2, wherein the impurity includes one of boron, phosphorus and arsenic.

8. The method of claim 1, wherein the gate layer has a thickness of between 500 to 1500 Å.

9. The method of claim 1, wherein the tunnel oxide layer has a thickness of between 50 to 150 Å.

10. A method comprising:
forming a plurality of shallow trench isolation layers in a semiconductor substrate having active regions;
forming a tunnel oxide layer over the active regions of the semiconductor substrate;
forming a gate layer over the semiconductor substrate including the shallow trench isolation layers and the tunnel oxide layer;
forming ion implantation regions in portions of the gate layer corresponding spatially to a respective one of the shallow trench isolation layers; and then
forming floating gates over the semiconductor substrate including the shallow trench isolation layers and the tunnel oxide layer.

11. The method of claim 10, wherein forming the shallow trench isolation layers comprises:
gap-filling the trenches with an insulating material; and then
polishing the insulation material using CMP.

12. The method of claim 11, wherein the insulation material comprises silicon oxide.

13. The method of claim 10, wherein forming the tunnel oxide layer comprises depositing the tunnel oxide layer by a thermal oxidization process.

14. The method of claim 13, wherein the tunnel oxide layer has a thickness of about 50 to 150 Å.

15. The method of claim 10, wherein the gate layer comprises doped polysilicon.

16. The method of claim 15, wherein the gate layer has a thickness of about 500 to 1500 Å.

17. The method of claim 10, wherein forming the ion implantation regions comprises:
implanting impurity ions in portions of the gate layer corresponding spatially to a respective one of the shallow trench isolation layers while also controlling at least one of the implantation energy and the implantation angle.

18. The method of claim 17, wherein the impurity ions comprises at least one of boron, phosphorus and arsenic.

19. The method of claim 10, wherein forming the gates comprises etching the ion implantation regions a dry etch process.

20. A method comprising:
forming a plurality of shallow trench isolation layers in a semiconductor substrate having active regions;
forming a tunnel oxide layer over the active regions of the semiconductor substrate;
forming a gate layer over the semiconductor substrate including the shallow trench isolation layers and the tunnel oxide layer;
forming photoresist patterns having apertures through which portions of the gate layer spatially corresponding to the isolation layers are exposed;
forming ion implantation regions by implanting impurity ions into the exposed portions of the gate layer using the photoresist patterns as masks;
forming floating gates by etching the ion implantation regions using the photoresist patterns as masks, and then
removing the photoresist patterns.
